(19) United States
(12) Patent Application Publication
(10) Pub. No.: US 2005/0145905 A1
(43) Pub. Date: Jul. 7, 2005

(54) Solid-state imaging device and production method of the same

(76) Inventor: Hiroshi Iwata, Fukuyama-shi (JP)

Correspondence Address: EDWARDS & ANGELL, LLP, P.O. BOX 55874, BOSTON, MA, 02205, US

(21) Appl. No.: 11/004,381

(22) Filed: Dec. 3, 2004

(30) Foreign Application Priority Data
Dec. 5, 2003 (JP) 2003-408343

(51) Int. Cl. H01L 31/062

(52) U.S. Cl. 257/292

(57) ABSTRACT

A solid-state imaging device is provided, which comprises unit pixel portions. Each unit pixel portion comprises a first conductivity type substrate, a second conductivity type semiconductor layer, a first conductivity type well region, a light receiving region for generating electric charges when irradiated with light, an electric charge accumulation region for accumulating the electric charges from the light receiving region, and a transistor capable of reading out a signal corresponding to an amount of the electric charges accumulated in the electric charge accumulation region. A surface of the light receiving region is covered with an insulating film made of the same material as that of a gate insulating film of the transistor.

This nonprovisional application claims priority below 35 U.S.C. §119(a) on Patent Application No. 2003-408343 filed in Japan on Dec. 5, 2003, the entire contents of which are hereby incorporated by reference.

### BACKGROUND OF THE INVENTION

1. Field of the Invention

The present invention relates to a solid-state imaging device, a threshold voltage modulation MOS image sensor, or the like, which is used in, for example, a camcorder, a digital camera, a cellular telephone with camera and the like; and a production method of the same.

2. Description of the Related Art

Conventionally, a CCD image sensor, a MOS image sensor and the like are known as solid-state imaging devices which convert image light to an electrical signal (image signal). The MOS image sensor has a light receiving region (photodiode), which generates electric charges when irradiated with light, and a transistor (MOS transistor), which reads out the electric charge generated in the light receiving region as a signal. The photodiode and the transistor are provided on the same substrate. The MOS image sensor has advantages of low power consumption, utilization of the standard MOS process technology for system LSI and the like (i.e., low cost), and versatility.

As an exemplary MOS image sensor, for example, Japanese Laid-Open Publication No. 2001-160620 discloses a threshold voltage modulation MOS image sensor. In the threshold voltage modulation MOS image sensor, a MOS transistor and a photodiode are provided on the same substrate, and an electric charge accumulation region called a hole pocket is formed below the gate electrode of the MOS transistor. Electric charges (holes) generated in the photodiode portion when irradiated with light are accumulated in the electric charge accumulation region. The threshold voltage of the MOS transistor is modulated in proportion to the amount of the accumulated electric charges. Therefore, a signal can be read out, corresponding to the amount of the accumulated electric charges.

Recently, as the standard CMOS process technology has been developed, a technology of forming a silicide layer on a surface of a high concentration diffusion region (diffusion layer), which is to be a source region or a drain region, or on a surface of a gate electrode, has been proposed so as to improve the performance of the MOS transistor.

The silicide layer is made of a compound of a high melting point metal, such as Ti, Co, Ni or the like, with Si. With the silicide layer, the resistance of the diffusion layer or the gate electrode of the MOS transistor can be reduced, leading to an increase in operating speed and a reduction in operating voltage.

For example, Japanese Laid-Open Publication No. 2002-83949 discloses a technique using the above-described technology. Specifically, in a MOS image sensor, a silicide layer is formed in the high concentration diffusion region excluding the photodiode portion in order to improve the sensitivity characteristics of the photodiode and the operating characteristics of the MOS transistor. This conventional technology will be described in detail with reference to FIG. 5.

FIG. 5 is a cross-sectional view showing a structure of a unit pixel of a conventional MOS image sensor, in which a silicide layer is formed on a surface of a diffusion layer or a gate electrode of a MOS transistor. Note that the MOS image sensor has a plurality of unit pixels arranged in rows and columns (i.e., in a matrix) though not shown in FIG. 5.

As shown in FIG. 5, the MOS image sensor 100 comprises a p-type substrate 50 made of silicon, a p-type well region 51 (a p-type diffusion region) which is provided on the p-type substrate 50, and a photodiode 52 and a MOS transistor 53 which are buried in the p-type well region 51.

The photodiode 52 is composed of an n-type diffusion layer 54b provided in the p-type well region 51, and a p-type diffusion layer 54a provided on a surface of the n-type diffusion layer 54b. Thus, the photodiode 52 has a buried photodiode structure. A light receiving surface of the photodiode 52 and its vicinity are covered with a multilayer antireflection film 55 in which two insulating films 55a and 55b having different refractive indexes are alternately layered.

In the p-type well region 51 of the MOS transistor 53, diffusion layers 56a and 56b which are to be a source region and a drain region are provided, and a gate oxide film 57 (silicon oxide film) is provided on an outermost surface of the p-type well region 51 interposed between the diffusion layers 56a and 56b. On the gate oxide film 57, a gate electrode 58 (polysilicon layer) is provided. A side wall 59 made of silicon oxide film is provided on sides of the gate electrode 58.

In the MOS image sensor 100, a Ti silicide layer 60 is provided on a surface of each of the diffusion layers 56a and 56b and the gate electrode 58 of the MOS transistor 53, thereby improving the operating characteristics of the MOS transistor 53.

No silicide layer is provided on a surface of the p-type diffusion layer 54a or the n-type diffusion layer 54b of the photodiode 52 to prevent a degradation in the sensitivity characteristics of a photomask.

Next, a method for producing the MOS image sensor 100 of FIG. 5 will be briefly described with reference to FIGS. 6A to 6D.

As shown in FIG. 6A, the photodiode 52 and the MOS transistor 53 are formed in the p-type well region 51 on the p-type substrate 50. On a region including the photodiode 52 and the MOS transistor 53, the insulating films 55a and 55b, which are respectively an oxide film and a nitride film, are alternately layered to provide the multilayer antireflection film 55.

Next, as shown in FIG. 6B, a mask pattern 61 is formed on the multilayer antireflection film 55 using photolithography.

Thereafter, as shown in FIG. 6C, the multilayer antireflection film 55 is removed by etching, except for the surface of the p-type diffusion layer 54a, which is to be the light receiving surface of the photodiode 52, and its vicinity.

Further, a high melting point metal layer made of Ti or Co, which is used for forming a silicide layer, is formed in a region including a surface of each of the multilayer antireflection film 55, the diffusion layers 56a and 56b which are to be respectively a source region and a drain region, and the gate electrode 58. By subjecting the whole structure to a predetermined thermal treatment, the surface of the high melting point metal layer is caused to react with the surfaces of the diffusion layers 56a and 56b and the gate electrode 58, thereby forming the silicide layer 60 as shown in FIG. 6D. Furthermore, the unreacted high melting point metal layer is removed. Thus, the MOS image sensor 100 is completed.

There is a demand for an improvement in the operating characteristics of the conventional threshold voltage modulation MOS image sensor 100. To achieve this, in the above-described conventional technology, the silicide layer 60 needs to be provided on the surface of each of the diffusion layers 56a and 56b (a source region and a drain region) and the gate electrode 58 of the MOS transistor 53.

However, when the silicide layer 60 is provided on the surface of the diffusion layer 54a in the photodiode 52, the sensitivity characteristics of the photodiode 52 is degraded. To avoid this, the step of forming a film for preventing the formation of silicide in the photodiode portion is required, resulting in an increase in manufacturing cost.

Also in the above-described conventional threshold voltage modulation MOS image sensor 100, the sensitivity of the photodiode 52 is reduced since incident light is reflected from the surface thereof. To avoid this, the step of forming the multilayer antireflection film 55 in the photodiode portion is required, resulting in an increase in manufacturing cost.

Further, in the conventional MOS image sensor 100 having the silicide layer 60, the step of forming the gate oxide film 57 (gate insulating film) of the MOS transistor 53 and the step of forming the silicide prevention film are requited in addition to the step of forming the multilayer antireflection film 55 for covering the surface of the photodiode 52, resulting in an increase in manufacturing cost.

### SUMMARY OF THE INVENTION

According to an aspect of the present invention, a solid-state imaging device is provided, which comprises a plurality of unit pixel portions in a two-dimensional manner. Each unit pixel portion comprises a first conductivity type substrate, a second conductivity type semiconductor layer provided on the first conductivity type substrate, a first conductivity type well region provided on the second conductivity type semiconductor layer, a light receiving region provided in the first conductivity type well region, the light receiving region generating electric charges when irradiated with light, an electric charge accumulation region provided in the first conductivity type well region, the electric charge accumulation region accumulating the electric charges from the light receiving region, and a transistor capable of reading out a signal corresponding to an amount of the electric charges accumulated in the electric charge accumulation region. A surface of the light receiving region is covered with an insulating film made of the same material as that of a gate insulating film of the transistor.

In one embodiment of this invention, a side wall is provided on a side of a gate electrode of the transistor.

In one embodiment of this invention, a silicide layer is provided on a surface of each of a source region, a drain region and a gate electrode of the transistor.

In one embodiment of this invention, the gate insulating film of the transistor and the insulating film covering the light receiving region are each a multilayer film comprising two or more insulating films having different refractive indexes.

According to another aspect of the present invention, a method is provided for producing a solid-state imaging device. The solid-state imaging device comprises a plurality of pixel portions each comprising a light receiving region for generating electric charges when irradiated with light, an electric charge accumulation region for accumulating the generated electric charges, and a transistor for reading out a signal corresponding to an amount of the accumulated electric charges. The method comprises forming a gate insulating film of the transistor and an insulating film covering a surface of the light receiving region simultaneously.

In one embodiment of this invention, the method comprises forming a gate electrode having a side wall on a side thereof on the gate insulating film.

In one embodiment of this invention, the method comprises patterning the insulating film after forming the gate electrode to expose a diffusion layer, which is to be a source region and a drain region of the transistor, leaving the gate insulating film below the gate electrode and the light receiving region covering film, forming a high melting point metal layer for forming a silicide layer over a region including the diffusion layer, the gate electrode of the transistor and the light receiving region covering film, forming the silicide layer on a surface of each of the diffusion layer and the gate electrode using a thermal treatment, and removing the unreacted high melting point metal layer.

In one embodiment of this invention, forming the insulating film comprises layering two or more insulating films having different refractive indexes.

Hereinafter, functions and effects of the present invention will be described.

According to the present invention, a solid-state imaging device, such as a MOS image sensor or the like, which comprises a plurality of unit pixel portions, is provided. Each unit pixel portion comprises a light receiving region (photodiode), an electric charge accumulation region, and a transistor (MOS transistor). The unit pixel portions are arranged in a two-dimensional manner. An insulating film (light receiving region covering film) covering the light receiving region is made of the same material as that for a gate insulating film of the transistor. The light receiving region covering film is formed at the same time as when the gate insulating film of the transistor is formed, i.e., no additional production step is required.

The gate insulating film and the light receiving region covering film function as a film for reducing damage when a side wall is formed, thereby making it possible to reduce leakage generating factors. Further, forming a silicide layer on a source region and a drain region of the transistor and a surface of the gate electrode, thereby making it possible to improve operating characteristics of the transistor. When the silicide layer is formed, the insulating film on the light receiving region functions as a film for preventing the formation of a silicide layer, thereby making it possible to prevent a reduction in sensitivity characteristics of the light receiving region.

Further, the gate insulating film and the light receiving region covering film may be each a multilayer film comprising two or more insulating films having different refractive indexes, thereby making it possible to function as an antireflection film. Therefore, a surface reflectance of the light receiving region can be reduced, thereby making it possible to improve the sensitivity characteristics.

Thus, according to the present invention, the surface of a diffusion layer serving as the source region and the drain region of the transistor and the surface of the gate electrode are made of silicide, thereby making it possible to reduce the resistance, and therefore, improve the operating speed of the transistor and reduce the operating voltage thereof. Further, the gate insulating film of the transistor and the insulating film (light receiving region covering film) covering the surface of the light receiving region (photodiode) can be formed simultaneously, whereby it is no longer necessary to provide a silicide formation preventing film. Furthermore, the gate insulating film and the light receiving region covering film can also function as a film for reducing damage when a side wall is formed. Therefore, it is possible to avoid leakage generating factors in addition to a reduction in manufacturing cost.

Furthermore, the gate insulating film and the light receiving region covering film may be each a multilayer film comprising two or more insulating films having different refractive indexes, thereby making it possible to reduce manufacturing cost and reduce the surface reflectance of the light receiving region to improve the sensitivity characteristics of the photodiode.

Thus, the invention described herein makes possible the advantages of providing a solid-state imaging device having improved operating characteristics of a MOS transistor and improved sensitivity characteristics of a photodiode and capable of being produced with low cost; and a production method thereof.

These and other advantages of the present invention will become apparent to those skilled in the art upon reading and understanding the following detailed description with reference to the accompanying figures.

### BRIEF DESCRIPTION OF THE DRAWINGS

FIG. 1 is a plan view showing an exemplary layout of a unit pixel portion in a MOS image sensor according to an embodiment of the present invention.

FIG. 2 is a cross-sectional view, taken along line A-A′ in FIG. 1.

FIGS. 3A to 3L are cross-sectional views sequentially showing exemplary steps of producing the MOS image sensor 10 of FIGS. 1 and 2.

FIGS. 4A to 4C are cross-sectional views sequentially showing exemplary steps of producing a MOS image sensor according to another embodiment of the present invention.

FIG. 5 is a cross-sectional view showing a structure of a conventional MOS image sensor.

FIGS. 6A to 6D are cross-sectional views of a conventional MOS image sensor.

### DESCRIPTION OF THE PREFERRED EMBODIMENTS

Hereinafter, the present invention will be described by way of illustrative examples with reference to the accompanying drawings. Particularly, a threshold voltage modulation MOS image sensor is described as a solid-state imaging device of the present invention.

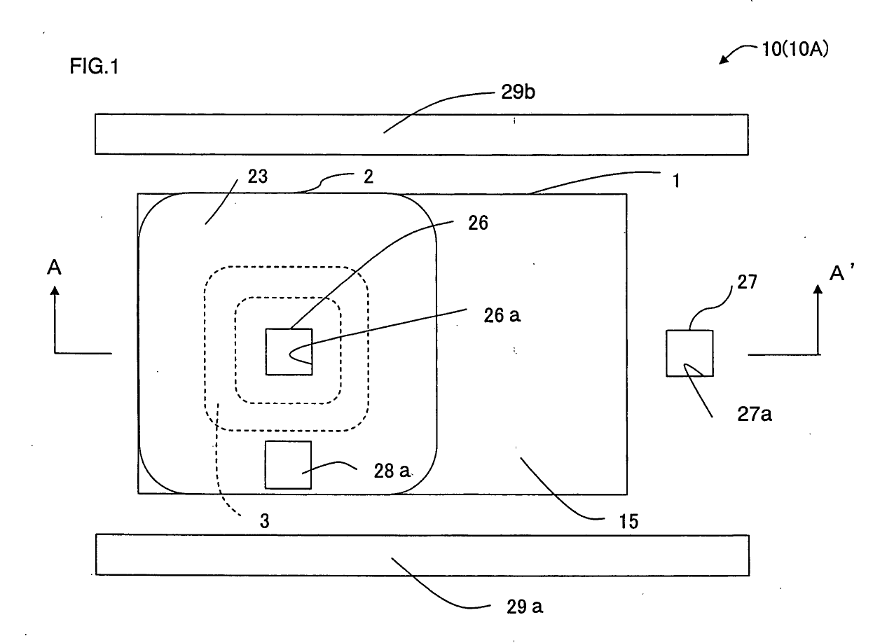

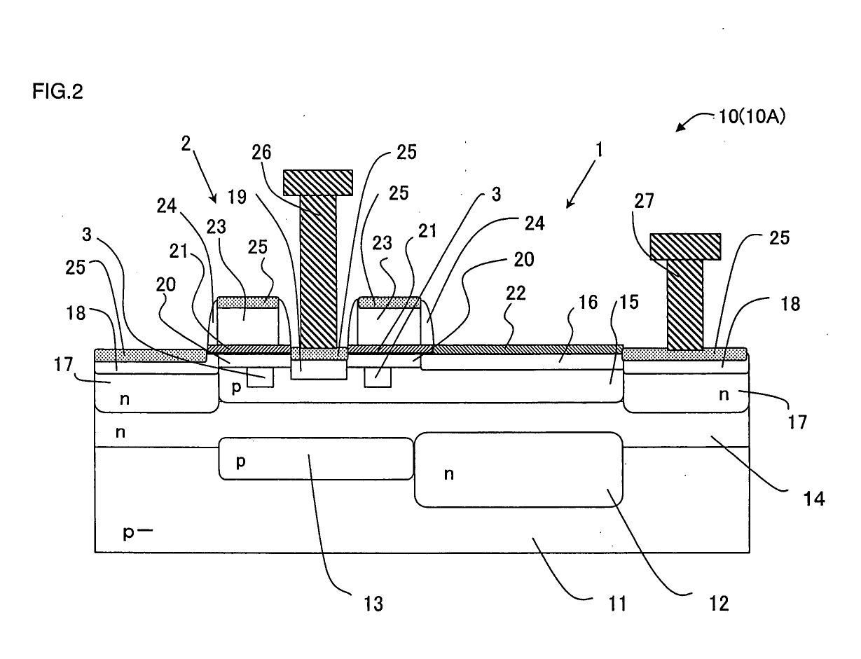

FIG. 1 is a plane view showing an exemplary unit pixel portion in a threshold voltage modulation MOS image sensor according to an embodiment of the present invention. FIG. 2 is a cross-sectional view of the unit pixel portion, taken along line A-A′ in FIG. 1. Note that the MOS image sensor (solid-state imaging device) has a plurality of unit pixel portions arranged in rows and columns (i.e., in a matrix (in a two-dimensional manner)) though not shown in FIGS. 1 and 2.

In FIGS. 1 and 2, the unit pixel portion 10A of the MOS image sensor 10 of the embodiment of the present invention has a light receiving diode 1 (photodiode) for photoelectric conversion, a MOS transistor 2 for detecting a light signal, which is provided adjacent to the light receiving diode 1, and a carrier pocket region 3 (hole pocket region) for accumulating electric charges, which is provided below the MOS transistor 2. The unit pixel portions 10A adjacent to one another in a row direction are separated via pixel isolation electrodes 29a and 29b, which are produced at the same time as when a gate electrode 23 is formed.

On a silicon substrate or an epitaxial semiconductor layer 11 (hereinafter referred to as a p-type substrate 11) provided on the silicon substrate, an n-type layer 14 is provided over a region for forming the photoelectric conversion light receiving diode 1 and a region for forming the light signal detection MOS transistor 2. An n-type layer 12 is provided below a portion of the n-type layer 14 in the light receiving diode 1 forming region, while a p-type buried layer 13 is provided below a portion of the n-type layer 14 in the MOS transistor 2 forming region. Further, a p-type well region 15 is provided over the light receiving diode 1 forming region and the MOS transistor 2 forming region on the n-type layer 14.

The p-type well region 15 is surrounded by a well isolation region 17, which defines a range for the formation of the p-type well region 15. The p-type well region 15 in the light receiving diode 1, i.e., a portion (light receiving region) of a region which generates electric charges when irradiated with light, serves as a photoelectric conversion portion. The p-type well region 15 in the light signal detection MOS transistor 2 serves as a transistor region of the MOS transistor 2, which can change a threshold voltage of a channel based on a potential which is in proportion to signal electric charges accumulated in the carrier pocket region 3 (electric charge accumulation region) provided in the p-type well region 15.

In the light receiving diode 1, an n-type impurity region 16 is provided on an upper surface of the p-type well region 15, forming a buried structure with respect to electric charges generated with light.

In the MOS transistor 2, the ring-shaped gate electrode 23 is provided over the p-type well region 15 via a gate insulating film 21. A source region 19 (n-type high concentration diffusion region (diffusion layer)) is provided in the ring-shaped gate electrode 23 and on the upper surface of the well region 15. Further, a drain region 18 (n-type high concentration diffusion region (diffusion layer)) is provided, surrounding an outer periphery of the p-type well region 15.

The well isolation region 17 is provided below the drain region 18. The drain region 18 is connected via the well isolation region 17 to the n-type layer 14. An n-type channel doped layer 20 is provided below the gate electrode 23 via the gate insulating film 21. The channel doped layer 20 forms a channel region (transistor region). An annular carrier pocket region 3 (hole pocket region) surrounding the source region 19 is provided below the channel region and in the p-type well region 15 in the vicinity of the source region 19.

In the hole pocket region 3, holes (light signal carriers) generated in the light receiving diode 1 when irradiated with light are accumulated. A threshold of the MOS transistor 2 is changed in proportion to the amount of light signal carriers accumulated in the hole pocket region 3.

A side wall film 24 is provided on side walls of the gate electrode 23. A silicide layer 25 is provided near surfaces of the gate electrode 23, the source region 19 and the drain region 18. The silicide layer 25 is made of a compound of a high melting point metal, such as Ti, Co, Ni or the like, with Si.

The source region 19 is connected via the silicide layer 25 and a contact hole 26a to a source electrode 26, and the drain region 18 is connected via the silicide layer 25 and a contact hole 27a to a drain electrode 27. The gate electrode 23 is connected via the silicide layer 25 and a contact hole 28a to a gate wiring (not shown).

Hereinafter, an operation of the above-described structure will be described.

In the MOS image sensor 10 (solid-state imaging device) of the embodiment of the present invention, a series of operations, i.e., initialization (reset)-electric charge accumulation-signal read out, are repeatedly performed.

During the initialization period, a high positive voltage is applied via the gate electrode 23 to the source electrode 26 and the drain electrode 27, so that light signal carriers remaining in the hole pocket region 3 are drained into the substrate 11.

Next, during the electric charge accumulation period, light signal carriers (holes) generated in the light receiving diode 1 when irradiated with light are accumulated via the p-type well region 15 into the hole pocket region 3 below the gate electrode 23.

During the signal read out period, a signal in proportion to the amount of light signal carriers accumulated in the hole pocket region 3 is output from the source region 19 and is detected.

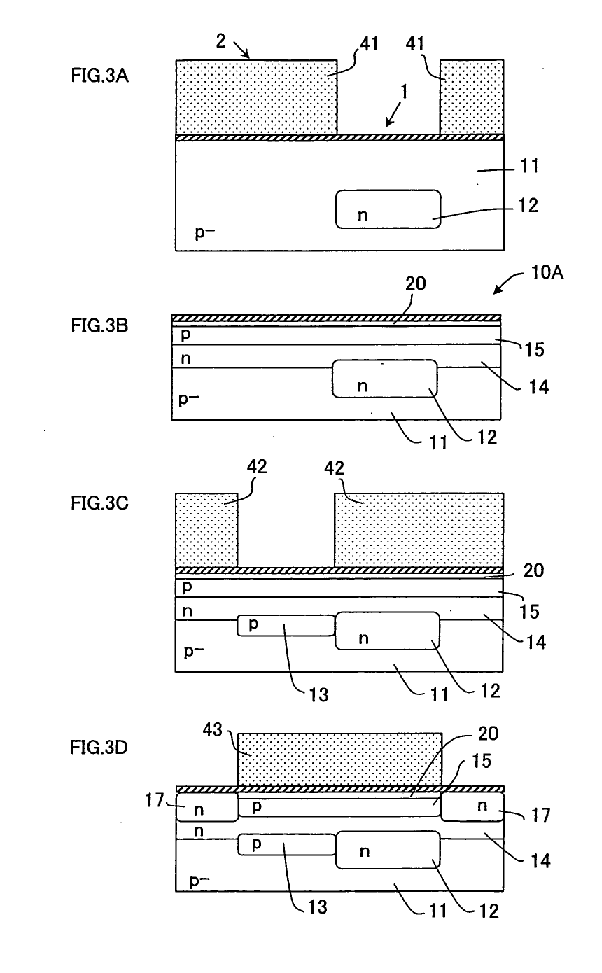

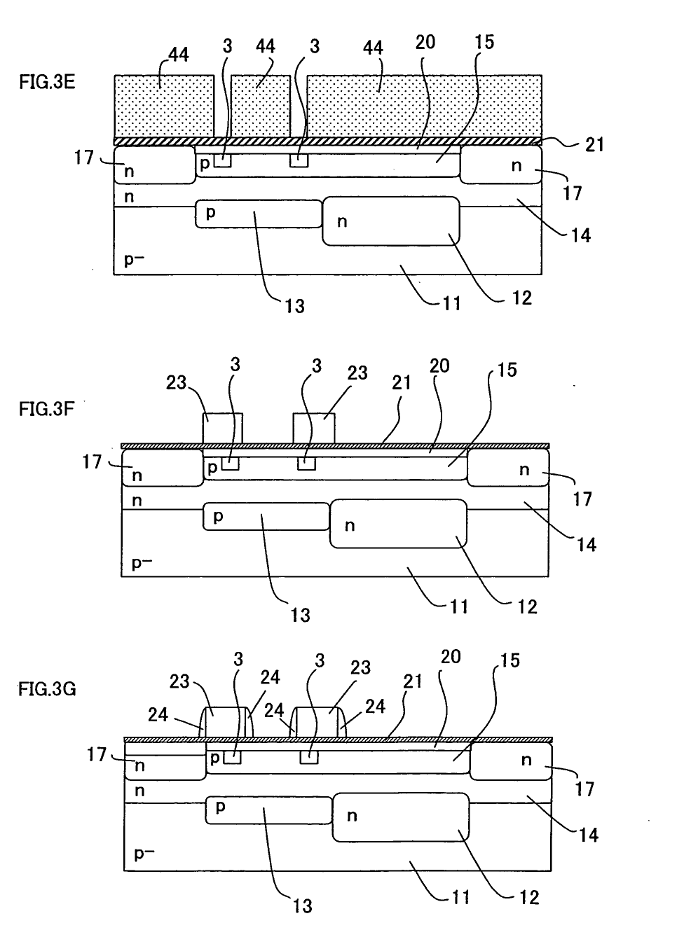

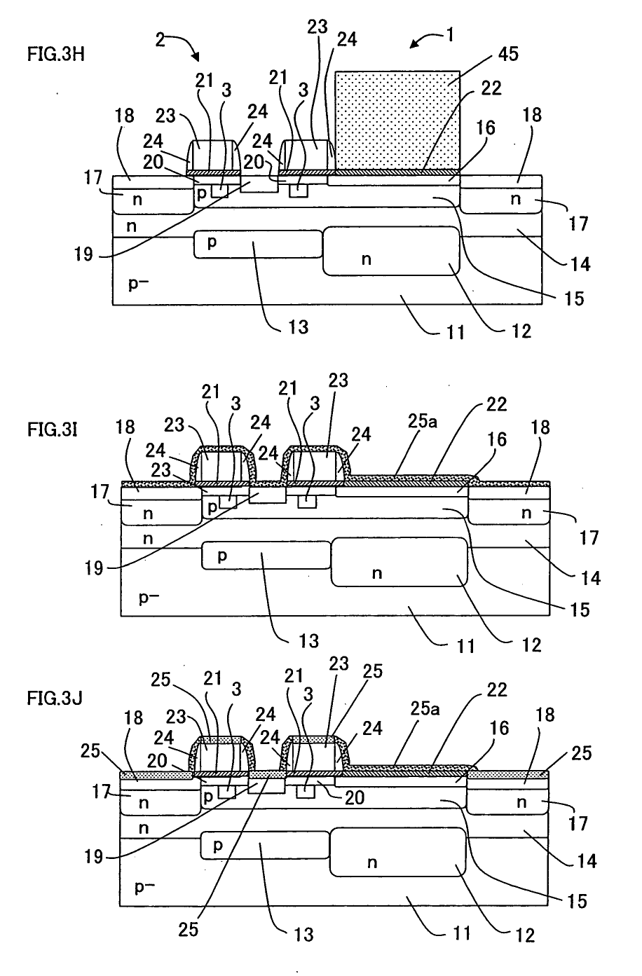

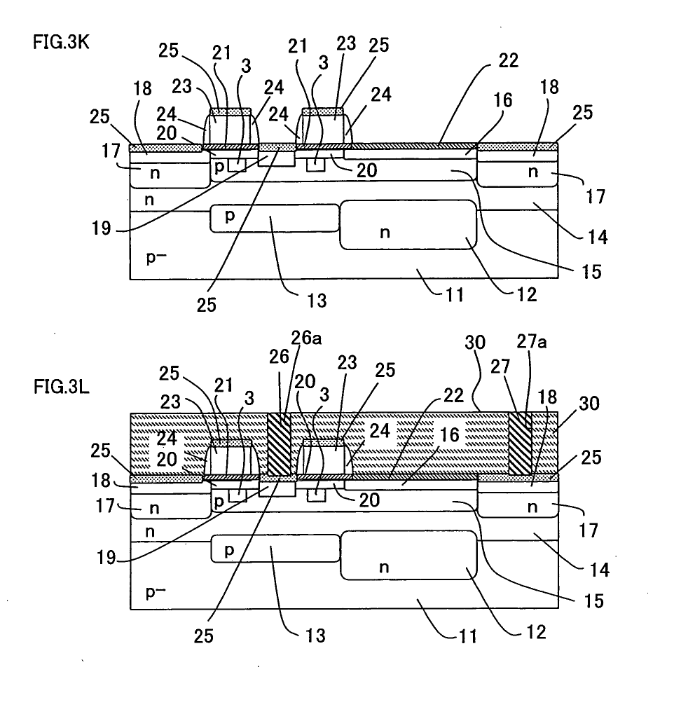

Hereinafter, a method for producing the MOS image sensor 10 of the embodiment of FIGS. 1 and 2 will be described with respect to FIGS. 3A to 3L.

FIGS. 3A to 3L are cross-sectional views sequentially showing steps of producing the MOS image sensor 10 of FIGS. 1 and 2. Note that these cross-sectional views correspond to the cross-sectional view taken along line A-A′ in FIG. 1.

As shown in 3A, a mask pattern film 41 having an opening corresponding to a region for forming the light receiving diode 1 is used to implant an impurity into the substrate 11 so that the n-type layer 12 is formed in the light receiving diode 1 forming region, where a peak position is about 1.5 μm, and a peak impurity concentration is about 1×10¹⁷ cm⁻³.

Next, as shown in FIG. 3B, the mask pattern film 41 is removed. An n-type impurity is implanted into the entire region of the unit pixel portion 10A so that the n-type layer 14 is formed on and connected to the n-type layer 12 of the light receiving diode 1, where a peak position is about 0.7 μm, and a peak impurity concentration is about 3×10¹⁶ cm⁻³. Further, a p-type impurity is implanted with a mask pattern being provided on the pixel isolation electrodes 29a and 29b so that the p-type well region 15 is formed on and connected to the n-type layer 14. An n-type impurity is implanted into an upper surface layer of the p-type well region 15 to form the n-type channel doped layer 20.

As shown in FIG. 3C, a mask pattern film 42 having an opening corresponding to a region for forming the light signal detection MOS transistor 2 is used to implant a p-type impurity below the n-type impurity layer 14 for the purpose of fixing the potential of the substrate, so that the p-type buried layer 13 having a higher impurity concentration than that of the n-type impurity layer 14 is formed adjacent to the n-type layer 12.

As shown in FIG. 3D, a mask pattern film 43 having an opening corresponding to a periphery of the p-type well region 15 is used to implant an n-type impurity into a region surrounding the p-type well region 15, thereby forming the well isolation region 17. As a result, the p-type well region 15 is separated into the well region of each unit pixel portion 10A, while a size of the light receiving diode 1, which determines sensitivity to a light signal, is defined to a predetermined area.

As shown in FIG. 3E, a mask pattern film 44 having an annular opening (in the shape of a ring surrounding the source region 19) corresponding to the hole pocket region 3 of the light signal detection MOS transistor 2 is used to implant a p-type impurity into the p-type well region 15 of the MOS transistor 2, so that the ring-shaped hole pocket region 3 having a higher impurity concentration than that of the p-type well region 15, where a peak position is about 0.15 μm and a peak impurity concentration is about 1.4×10¹⁷ cm⁻³.

After the mask pattern film 44 is removed, a surface of the semiconductor substrate is subjected to thermal oxidation to form the gate insulating film 21 (not shown). The gate insulating film 21 is a transparent film, and also has a function as a film 22 for preventing the formation of a silicide layer as described below. For example, the gate insulating film 21 is a silicon oxide film having a thickness of about 500 angstroms. In the threshold voltage modulation MOS image sensor 10 of the present invention, the sensitivity is increased in proportion to the thickness of the gate insulating film 21. Therefore, the above-described thickness of the gate insulating film 21 is beneficial.

As shown in FIG. 3F, the ring-shaped gate electrode 23 is formed on the gate insulating film 21 so that the hole pocket region 3 is covered therewith and the hole pocket region 3 is disposed close to the source region 19.

As shown in FIG. 3G, a silicon oxide film layer (SiO₂, etc.) for forming a side wall is formed on the entire structure. Thereafter, the side wall film 24 is formed on the side walls of the gate electrode 23 by dry etching. The side wall film 24 prevents a degradation in characteristics, such as a hot carrier phenomenon or the like, in the MOS transistor 2, and also functions to spatially isolate the silicide layer 25 formed on the surfaces of the gate electrode, the source region and the drain region. A surface of the light receiving diode 1 is covered with the gate insulating film 21 (surface covering film) made of silicon oxide or the like. The gate insulating film 21 also functions to reduce an influence of image noise due to PN junction leakage caused by a defect, since plasma damage due to dry etching can be avoided when forming the side wall.

As shown in FIG. 3H, a mask pattern film 45 having an opening corresponding to a region other than the surface of the light receiving diode 1 is used to perform wet etching to the region, thereby exposing the silicon, leaving the silicide layer formation preventing film 22 on the surface of the light receiving diode 1. The same mask pattern film 45 is used to form the n-type source region 19 as a surface layer of the well region 15 in a region for forming the MOS transistor 2 in the ring-shaped gate electrode 23, thereby forming the drain region 18 surrounding an outer periphery of the gate electrode 23. In this case, since the light receiving diode 1 is covered with the mask pattern film 45, the n-type impurity region 16 is formed on the surface layer of the light receiving diode 1. After the mask pattern film 45 is removed, an n-type impurity is implanted to form the n-type impurity region 16.

As shown in FIG. 3I, a high melting point metal layer 25a made of Ti, Co or the like is formed over a region including the surface of each of the silicide formation preventing film 22, the source region 19, the drain region 18 and the gate electrode 23 to form the silicide layer 25.

As shown in FIG. 3J, silicon of the surface of each of the source region 19, the drain region 18 and the gate electrode 23 is caused to react with the high melting point metal layer 25a using a predetermined thermal treatment to obtain the silicide layer 25.

As shown in FIG. 3K, the unreacted high melting point metal layer 25a is removed using a mixture of sulfuric acid and hydrogen peroxide solution, and further, the silicide layer 25 is removed using a mixture of ammonia water and hydrogen peroxide solution to a desired thickness.

As shown in FIG. 3L, an interlayer insulating film 30 is formed and perforated to provide the contact holes 26a, 27a and 28a corresponding to the source region 19, the drain region 18 and the gate electrode 23, respectively, thereby forming the source electrode 26, the drain electrode 27 and the gate electrode (not shown).

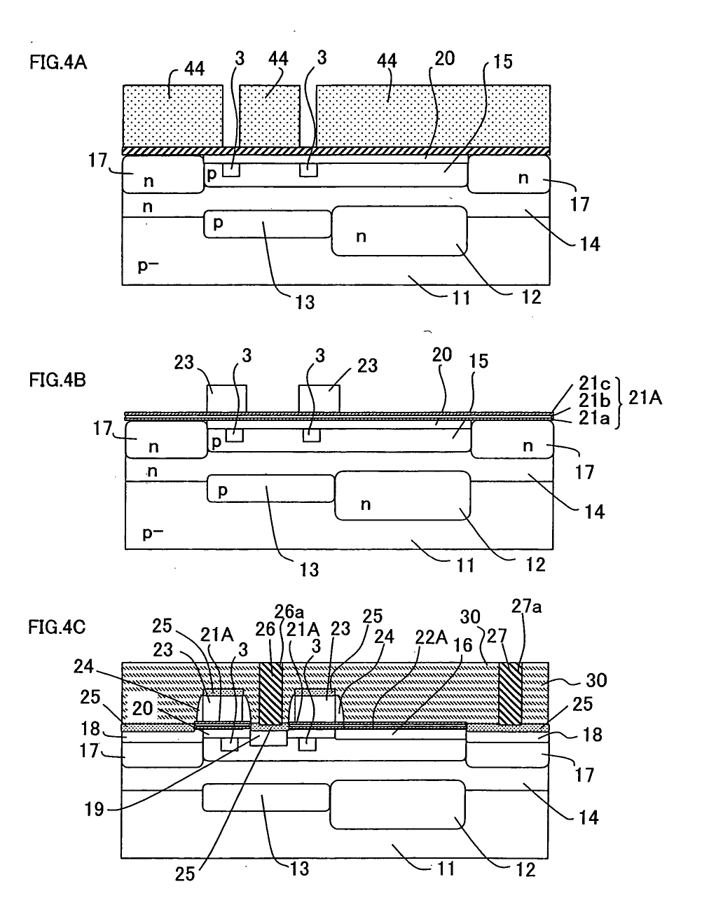

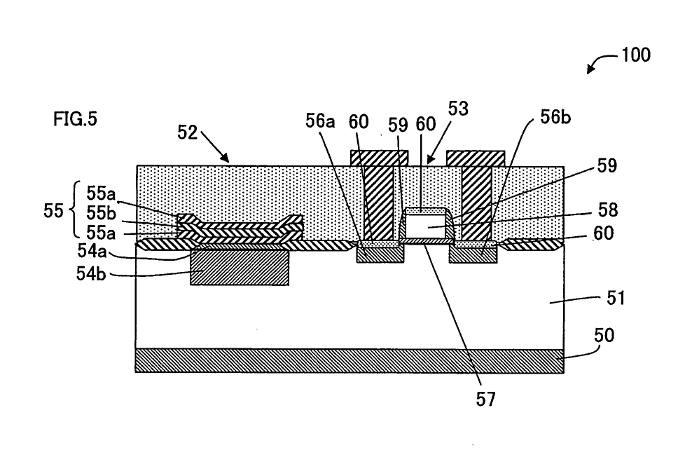

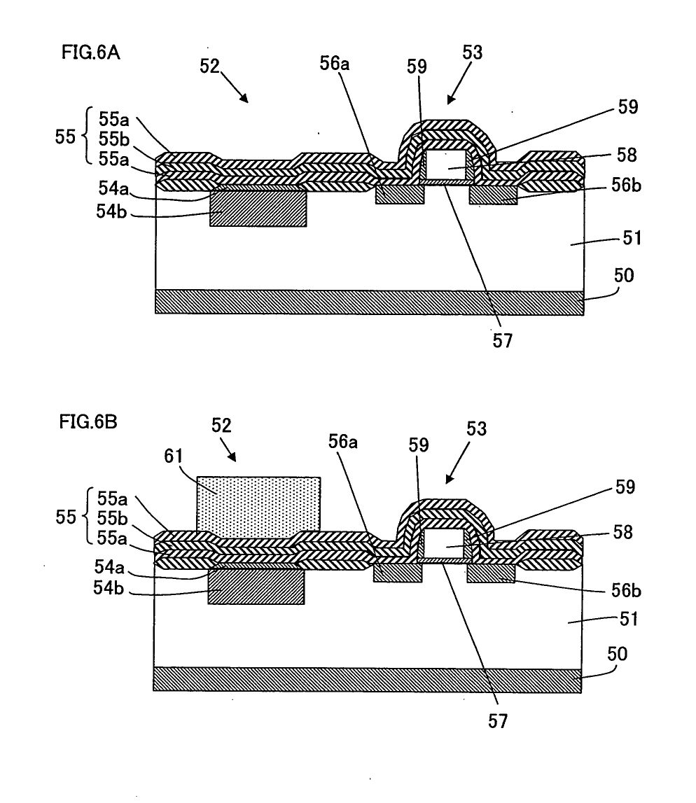

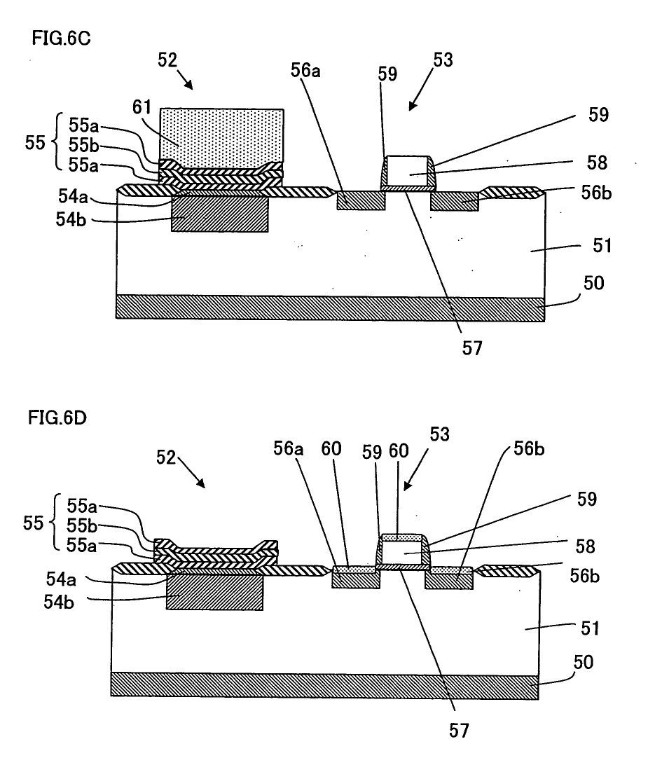

Note that the solid-state imaging device (MOS image sensor 10) of the present invention can be produced using a method which will be hereinafter described with reference to FIGS. 4A to 4C.

Similar to FIGS. 3A to 3E, as shown in FIG. 4A, each diffusion layer is formed on the p-type substrate 11.

Next, as shown in FIG. 4B, a gate insulating film 21a (silicon oxide film) is obtained by thermal oxidation. On the gate insulating film 21a, a gate insulating film 21b (silicon nitride film) and a gate insulating film 21c (silicon oxide film) are successively layered using a reduced-pressure CVD technique to provide a multilayer gate insulating film 21A. In this case, a total thickness is preferably about 500 angstroms or more. It is desirable that the multilayer gate insulating film 21A has a multilayer structure of silicon oxide film-silicon nitride film-silicon oxide film because of good interface controllability with respect to silicon. However, the present invention is not limited to such a combination.

Similar to FIGS. 3F to 3L, as shown in FIG. 4C, the MOS image sensor can be produced.

In the solid-state imaging device (MOS image sensor 10) thus produced, the silicide formation preventing film 22 is an insulating film (transparent film) which is formed at the same time as when the multilayer gate insulating film 21A is formed, thereby providing a multilayer structure. When the multilayer structure has two or more films having different refractive indexes, which are layered taking optical film thickness into consideration, the surface reflectance of the light receiving region can be suppressed to a low level in a broader wavelength range as compared to a monolayer film.

Thus, according to the embodiment of the present invention, the gate insulating film 21 or 21A of the MOS transistor 2 is formed at the same time as when the silicide formation preventing film 22 or 22A are formed on the light receiving diode 1. Therefore, no new formation preventing film needs to be formed in the region for preventing the formation of the silicide layer 25. Further, the gate insulating films 21 or 21A and the silicide formation preventing film 22 or 22A can also function as a film for reducing damage when the sidewall 24 is formed, thereby making it possible to avoid leakage generating factors. Furthermore, by providing multilayers, such as the gate insulating film 21A and the silicide formation preventing film 22A, the surface reflectance of the light receiving diode 1 can be reduced, thereby improving the sensitivity characteristics thereof.

Note that the present invention is not limited to the above-described embodiment. In order to obtain similar effects when an n-type substrate is used, the conductivity type of each layer and each region may be reversed with respect to those described in the above embodiment. Although not specified in the above-described embodiment, when a high speed operation is required only for a peripheral circuit (e.g., a logic circuit, such as an A/D converter, a shift register, or the like) and a high speed operation which would be achieved by using the silicide layer 60 in the unit pixel 10A is not required, the silicide formation preventing film 22 formed on the surface of the light receiving diode 1 is no longer required, thereby further reducing mask.

The present invention is applicable in the field of, for example, a solid-state imaging device, such as a threshold voltage modulation MOS image sensor or the like, which is used in a camcorder, a digital camera, a cellular telephone with camera, and the like, and a production method thereof. According to the present invention, when the silicide layer for improving transistor operating characteristics is formed, the surface of the light receiving region is covered with the insulating film which is formed at the same time as when the gate insulating film is formed, thereby making it possible to reduce the sensitivity characteristics of the photodiode. Further, the gate insulating film and the light receiving region covering film also function to reduce damage when the side wall of the gate electrode is formed, thereby avoiding leakage generating factors and therefore improving the reliability. Furthermore, two or more insulating films having different refractive indexes are layered so that the surface reflectance of the light receiving region is reduced, thereby making it possible to improve the sensitivity characteristics of the photodiode. Thus, the solid-state imaging device of the present invention has excellent transistor characteristics and photodiode characteristics, and can be produced with low cost. Therefore, the solid-state imaging device of the present invention can be applied to a wide variety of electronic information apparatuses, such as a camcorder, a digital camera, a cellular telephone with camera, and the like.

Although certain preferred embodiments have been described herein, it is not intended that such embodiments be construed as limitations on the scope of the invention except as set forth in the appended claims. Various other modifications and equivalents will be apparent to and can be readily made by those skilled in the art, after reading the description herein, without departing from the scope and spirit of this invention. All patents, published patent applications and publications cited herein are incorporated by reference as if set forth fully herein.

1. A solid-state imaging device, comprising a plurality of unit pixel portions in a two-dimensional manner, wherein each unit pixel portion comprises:
a first conductivity type substrate;
a second conductivity type semiconductor layer provided on the first conductivity type substrate;
a first conductivity type well region provided on the second conductivity type semiconductor layer;
a light receiving region provided in the first conductivity type well region, the light receiving region generating electric charges when irradiated with light;
an electric charge accumulation region provided in the first conductivity type well region, the electric charge accumulation region accumulating the electric charges from the light receiving region; and
a transistor capable of reading out a signal corresponding to an amount of the electric charges accumulated in the electric charge accumulation region,
wherein a surface of the light receiving region is covered with an insulating film made of the same material as that of a gate insulating film of the transistor.

2. A solid-state imaging device according to claim 1, wherein a side wall is provided on a side of a gate electrode of the transistor.

3. A solid-state imaging device according to claim 1, wherein a suicide layer is provided on a surface of each of a source region, a drain region and a gate electrode of the transistor.

4. A solid-state imaging device according to claim 1, wherein the gate insulating film of the transistor and the insulating film covering the light receiving region are each a multilayer film comprising two or more insulating films having different refractive indexes.

5. A method for producing a solid-state imaging device, wherein the solid-state imaging device comprises a plurality of pixel portions each comprising:
a light receiving region for generating electric charges when irradiated with light;
an electric charge accumulation region for accumulating the generated electric charges; and
a transistor for reading out a signal corresponding to an amount of the accumulated electric charges,
the method comprising:
forming a gate insulating film of the transistor and an insulating film covering a surface of the light receiving region simultaneously.

6. A method according to claim 5, comprising:
forming a gate electrode having a side wall on a side thereof on the gate insulating film.

7. A method according to claim 6, comprising:
patterning the insulating film after forming the gate electrode to expose a diffusion layer, which is to be a source region and a drain region of the transistor, leaving the gate insulating film below the gate electrode and the light receiving region covering film;
forming a high melting point metal layer for forming a silicide layer over a region including the diffusion layer, the gate electrode of the transistor and the light receiving region covering film;
forming the silicide layer on a surface of each of the diffusion layer and the gate electrode using a thermal treatment; and
removing the unreacted high melting point metal layer.

8. A method according to claim 5, wherein forming the insulating film comprises layering two or more insulating films having different refractive indexes.
